(19) United States
(12) Patent Application Publication
(10) Pub. No.: US 2022/0201897 A1
(43) Pub. Date: Jun. 23, 2022

(54) COOLING MODULE FOR AN ELECTRICAL ASSEMBLY

(71) Applicant: Valeo Siemens eAutomotive France SAS, Cergy (FR)

(72) Inventors: Alexandre Legendre, Cergy (FR); Aurelien Pouilly, Cergy (FR)

(73) Assignee: Valeo Siemens eAutomotive France SAS, Cergy (FR)

(21) Appl. No.: 17/644,645

(22) Filed: Dec. 16, 2021

(30) Foreign Application Priority Data
Dec. 18, 2020 (FR) 2013705

(51) Int. Cl. H05K 7/20

(52) U.S. Cl. CPC H05K 7/20272; H05K 7/20872; H05K 7/20927

(57) ABSTRACT

A cooling unit for dissipating the heat generated by electronic components (40) of an electrical assembly (1) is disclosed. The cooling unit has a first portion (20) and a second portion (30), each of which form a hollow part, of substantially parallelepipedal shape. The first and second portions meet at a joining zone (51) of the cooling unit, the first and second portions each comprising a first external surface that is turned towards the other portion, and said first external surfaces each comprising a receiving zone intended to receive one or more of said electronic components (40). At least one of said portions comprises a connection opening configured to be connected to another part of said cooling module (10) that is separate from said cooling unit. The cooling unit also comprises at least one orifice (55) formed in one of the portions.

### TECHNICAL FIELD AND SUBJECT MATTER OF THE INVENTION

The present invention relates to the field of electrical apparatuses, in particular for vehicles, in particular for electric vehicles (“EVs”) or hybrid vehicles (“HEVs”).

The invention relates more particularly to an electrical assembly comprising a cooling module used to dissipate the heat generated by electronic components of said electrical assembly.

### PRIOR ART

A power electronic unit for an electric or hybrid vehicle, such as an inverter, comprises electronic components that generate a considerable amount of heat, such as power electronic components and capacitive components. The number of power electronic components can correspond to the number of phases of a motor controlled by the inverter (which is for example equal to three).

During the operation of a power electronic unit, the electronic components heat up and therefore have to be cooled so as to be operational at their optimal efficiency. Effective cooling of the electronic components makes it possible to increase the service life of the electronic components. The power electronic unit thus comprises a cooling module for dissipating the heat generated by these electronic components.

Depending on the shapes and locations of these electronic components, the shape and the structure of the cooling module may be complicated and difficult to manufacture. Thus, cooling modules exist that are composed of a plurality of cooling pieces of different shapes and structures so as to adapt to the electronic components.

Nevertheless, there are problems regarding assembly and interconnection of the electronic components and cooling pieces. Assembly may be very complicated to realize.

There is therefore a need for a cooling module that is easy to assemble, less bulky and less expensive, lighter and more robust than conventional cooling systems.

### GENERAL DESCRIPTION OF THE INVENTION

In order to achieve this result, the present invention relates to a cooling unit for forming a cooling module configured to dissipate the heat generated by electronic components of an electrical assembly, the cooling unit comprising a first portion and a second portion, each of which are of substantially parallelepipedal shape and form a respective hollow part. The cooling unit according to the invention is noteworthy in that:

the first and second portions meet at a joining zone of the cooling unit, the first and second portions each comprising a first external surface that is turned towards the other portion, and said first external surfaces each comprising a receiving zone intended to receive one or more of said electronic components;

at least one of said portions comprises a connection opening configured to be connected to another part of said cooling module that is separate from said cooling unit;

the cooling unit also comprises at least one orifice formed in one of the portions, called inlet/outlet portion, the orifice opening into the hollow part of said portion, the orifice being used as a fluid inlet or a fluid outlet of the cooling module.

The cooling units according to the invention have a simple and robust structure. They are easy to manufacture (e.g. to mould) and to assemble so as to form a cooling circuit.

In particular, said first external surfaces form an angle with one another.

In particular, the at least one connection opening is configured to be connected to another part of said cooling module in a sealed manner.

Advantageously, the first portion comprises a connection opening situated at an end of the first portion that is distal from the joining zone of the cooling unit.

Advantageously, the second portion comprises a connection opening that is formed at its first external surface, and is situated in a zone that is different from the receiving zone of said first external surface of the second portion.

Advantageously, the hollow parts are configured to allow the circulation of a cooling fluid.

According to one embodiment, an interior angle between the first and second portions of the cooling unit is equal to 90 degrees.

Advantageously, the orifice is formed on a second external surface of the inlet/outlet portion, said second external surface being opposite said first external surface of the inlet/outlet portion.

The invention also relates to a cooling module.

The cooling module is composed of identical cooling units, and this makes it possible both to simplify the manufacture of the cooling module and of the electrical assembly and also to adapt it to various electronic components. There is no longer a need to manufacture cooling pieces of various shapes and structures.

The cooling module is intended to be integrated in an electrical assembly of an electric or hybrid motor vehicle so as to dissipate the heat generated by electronic components of the electrical assembly, and comprises cooling units respectively as briefly described above.

According to one embodiment, the cooling units are assembled so as to form a fluid cooling circuit configured to convey a cooling fluid.

Advantageously:

a number of cooling units is equal to two;

for each of the cooling units, the first portion comprises a first connection opening, and the second portion comprises a second connection opening;

the first and second connection openings of one of the cooling units are respectively connected, in a sealed manner, to the second connection opening and to the first connection opening of the other of the cooling units.

According to one embodiment, the orifice of one of the cooling units, and that of the other of the cooling units, are respectively used as a fluid inlet and as a fluid outlet of the cooling module.

Advantageously, the cooling module comprises the cooling fluid used to dissipate the heat generated by the electronic components.

The invention also relates to an electrical assembly for an electric or hybrid motor vehicle, comprising electronic components and a cooling module as briefly described above.

Advantageously, the electronic components comprise one or more power electronic components, and/or one or more capacitive components.

According to one embodiment, said electrical assembly forms an inverter or a DC-to-DC voltage converter.

### PRESENTATION OF THE FIGURES

The invention will be better understood upon reading the following description, which is given by way of example, and referring to the following figures, which are given by way of non-limiting examples, in which identical references are given to similar objects.

FIG. 1 illustrates, according to an embodiment of the invention, a view of a cooling module before assembly, the cooling module being intended to be integrated in an electrical assembly;

FIG. 2 illustrates a view of the electrical assembly with the cooling module integrated after assembly, according to an embodiment of the invention; and

FIG. 3 illustrates a view of the electrical assembly, the cooling units of the cooling module according to an embodiment of the invention being transparent so as to show the circulation of a cooling fluid

It should be noted that the figures explain the invention in detail in order to implement the invention, it being of course possible for said figures to serve to better define the invention if necessary.

### DETAILED DESCRIPTION OF THE INVENTION

The invention relates to a cooling module 10, which is intended to be integrated in an electrical assembly 1 configured to be installed on board an electric or hybrid motor vehicle. The electrical assembly 1 is, for example, a power electronic unit, in particular an inverter or a DC-to-DC voltage converter.

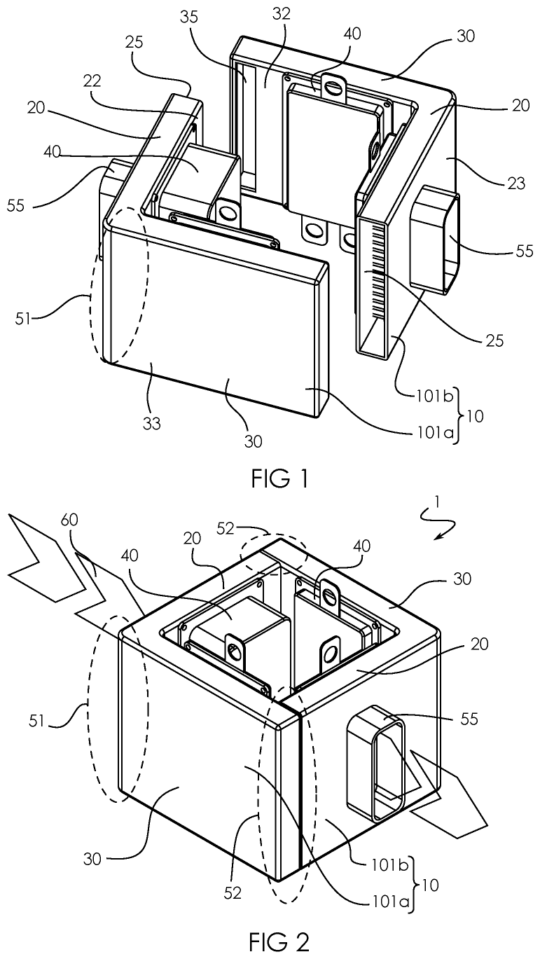

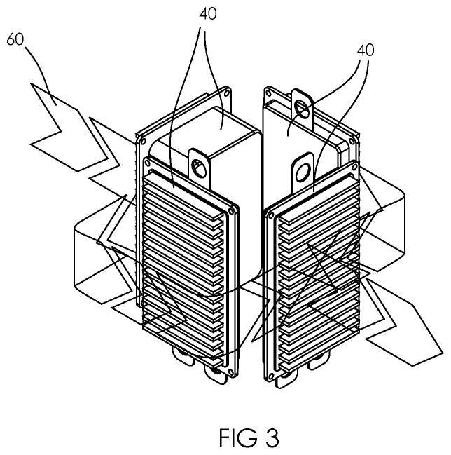

FIG. 1 and FIG. 2 illustrate a view of the cooling module 10 before and after assembly, according to an embodiment of the invention. FIG. 3 illustrates a view of the electrical assembly 1, the cooling units of the cooling module 10 being transparent so as to show circulation of a cooling fluid 60. The cooling fluid 60 is for example water or liquid glycol.

The electrical assembly 1 comprises electronic components 40 that generate heat during operation. The electronic components 40 comprise one or more power electronic components, and/or one or more capacitive components. For example, the electrical assembly 1 comprises four electronic components 40 of which one is a capacitive component while the other three are power electronic components that correspond respectively to one of the three phases of a motor controlled by the inverter 1. Nevertheless, the invention is not limited as regards the number of electronic components 40 or the types of electronic components 40.

The cooling module 10 comprises cooling units. Assembly of the cooling units makes it possible to form a fluid cooling circuit configured to convey the cooling fluid 60. In the example illustrated in FIGS. 1 to 3, the cooling module 10 comprises two cooling units 101a and 101b. The invention can comprise more cooling units, depending on the shape and structure of the desired cooling module 10. In another embodiment in which the cooling module 10 is in the shape of a hexagon, the cooling module 10 is composed of three cooling units.

In particular, the cooling units 101a, 101b of the cooling module 10 are identical in terms of structure, operation and, preferably, material. The cooling unit (101a or 101b) is preferentially constituted of a material such as aluminium of AlSi12(Fe) type. Alternatively, the cooling unit (101a or 101b) can be constituted of filled plastic of PA66 GF30 type or any other material having mouldability and mechanical integrity capacities that are suited to use in a power electronic unit such as an inverter. The cooling unit has a hollow structure that allows the circulation of the cooling fluid 60.

The cooling units each comprise a first portion 20 and a second portion 30. The first and second portions 20, 30 each form a hollow part of substantially parallelepipedal shape. Said first and second portions 20, 30 each have a first external surface 22, 32, which is respectively turned towards the external surface of the other portion. Said respective first external surfaces 22, 32 each comprise a receiving zone intended to receive one or more of the electronic components 40. The cooling units are also used as holding supports for fastening and holding the electronic components 40 in position.

At least one of the first and second portions 20, 30 of the cooling unit (101a or 101b) comprises a connection opening configured to be connected, in a sealed manner, to another part of the same cooling module 10 that is separate from said cooling unit. Said other part of the cooling module 10 may be another cooling unit of said cooling module 10.

The first and second portions 20 and 30 of the cooling unit (101a or 101b) meet at a joining zone 51 of the cooling module 10. Preferentially, the two portions 20, 30 and the joining zone 51 of the cooling unit are formed in one piece. In particular, an interior angle is formed between the two portions 20 and 30 of the cooling unit. In one embodiment, the interior angle of the cooling unit is equal to 90 degrees. In this case, the cooling unit is L-shaped. It should be noted that the interior angle may be greater or less than 90 degrees. For example, in another embodiment in which the cooling module 10 is in the shape of a hexagon, the interior angle of each cooling unit is 120 degrees.

In one embodiment, the first portion 20 of the cooling module 10 comprises a first external surface 22, a second external surface 23 that is opposite, and in particular parallel, to the first external surface 22, a (first) connection opening 25 and a hollow part. Similarly, the second portion 30 comprises a first external surface 32, a second external surface 33 that is opposite, and in particular parallel, to the first external surface 32, a (second) connection opening 35 and a hollow part. The interior angle between the two portions 20 and 30 is then defined by the first external surfaces 22 and 32.

The cooling unit also comprises an orifice 55 formed either in the first portion 20 (as described in the example in FIGS. 1 to 3) or in the second portion 30 (not described by the figures). The orifice 55 is used as a fluid inlet or a fluid outlet of the cooling module 10. The orifice 55, which opens into the hollow part of the first portion 20 or that of the second portion 30, is formed at the second external surface 23 of the first portion 20, or at the second external surface 33 of the second portion 30. Preferentially, the cooling unit and its orifice 55 are formed in one piece.

As described above, the first external surfaces 22, 32 each comprise a receiving zone intended to receive one or more of said electronic components 40. More specifically, the one or more electronic components 40 respectively comprise a surface that is in contact with the receiving zone of the first external surface 22 of the first portion or with that of the first external surface 32 of the second portion. Thus, the heat generated during operation of the electronic components 40 can be dissipated by contact with the receiving zones of the first external surfaces 22, 32 and also by the cooling fluid 60 circulated in the hollow parts of the cooling unit 101a or 101b.

For the cooling unit, the first connection opening 25 is situated at an end of the first portion 20 that is distal from the joining zone 51. The second connection opening 35 is situated towards an end of the second portion 30. Preferably, the second connection opening 35 is formed at the first external surface 32, being situated in a zone that is different from the receiving zone of the first external surface 32, as illustrated in FIG. 1.

The first connection opening 25 of one of the cooling units (e.g. “101a”) is configured to be connected in a sealed manner to the second connection opening 35 of the other of the cooling units (e.g. “101b”). A sealed join 52 of the cooling module 10 is thus formed during assembly. Similarly, the second connection opening 35 of one of the cooling units (e.g. “101a”) is configured to be connected in a sealed manner to the first connection opening 25 of the other of the cooling units (e.g. “101b”). Another sealed join 52 is therefore formed during assembly, as illustrated in FIGS. 1 and 2. The sealed joins 52 of the cooling module 10 allow circulation of the cooling fluid 60 in the cooling module composed of the separate cooling units, without leakage of the cooling fluid 60.

It should be noted that, in order to make the testing and manufacturing phases easier, the electronic components 40 can be mounted on the cooling units, prior to assembly of the cooling units. Electrical sub-assemblies are thus formed. For example, the cooling unit 101a and the electronic components 40 mounted thereon form an electrical sub-assembly, and the cooling unit 101b and the electronic components 40 mounted thereon form another electrical sub-assembly.

The electrical sub-assemblies can be tested separately, and this therefore makes it possible to reduce the cost associated with end-of-line rejects. Assembly of the electrical sub-assemblies therefore forms the electrical assembly 1.

After assembly of the cooling units (or assembly of the electrical sub-assemblies), the cooling fluid 60 can therefore circulate in the hollow parts of the cooling units 101a and 101b of the cooling module 10, from the fluid inlet (e.g. the orifice 55 of the cooling unit 101a) towards the fluid outlet (e.g. the orifice 55 of the cooling unit 101b) of the cooling module 10, as described in FIGS. 2 and 3. Compared with conventional cooling modules, such a cooling module 10 no longer has problems regarding the interconnection of the electronic components and cooling units.

The present invention therefore has a number of advantages. The cooling units have a simple and robust structure. They are easy to manufacture (e.g. to mould) and to assemble so as to form a cooling circuit. The cooling module is composed of preferably identical cooling units, and this makes it possible both to simplify the manufacture of the cooling module and of the electrical assembly and also to adapt it to various electronic components. It is thus no longer necessary to manufacture cooling module elements of various shapes and structures.

The cooling module according to the invention and also the electrical assembly in which the cooling module is integrated, are less bulky and less expensive, lighter and more robust than conventional cooling systems and electrical assemblies.

The invention is not limited to the embodiments described above but encompasses any embodiment that is in accordance with the spirit thereof.

1. A cooling unit for forming a cooling module configured to dissipate the heat generated by electronic components of an electrical assembly the cooling unit comprising:
a first portion and a second portion, each of which are of substantially parallelepipedal shape and form a respective hollow part,
wherein the first and second portions meet at a joining zone of the cooling unit, the first and second portions each comprising a first external surface that is turned towards the other portion, and said first external surfaces each comprising a receiving zone intended to receive one or more of said electronic components,
wherein at least one of said first and second portions comprises a connection opening configured to be connected to another part of said cooling module that is separate from said cooling unit; and
at least one orifice formed in one of the first and second portions, called inlet/outlet portion, the orifice opening into the hollow part of said corresponding first or second portion,
the orifice being used as a fluid inlet or a fluid outlet of the cooling module.

2. The cooling unit according to claim 1, wherein the first portion comprises a connection opening situated at an end of the first portion that is distal from the joining zone of the cooling unit.

3. The cooling unit according to claim 1, wherein the second portion comprises a connection opening that is formed at its first external surface, and is situated in a zone that is different from the receiving zone of said first external surface of the second portion.

4. The cooling unit according to claim 1, wherein the hollow parts are configured to allow the circulation of a cooling fluid.

5. The cooling unit according to claim 1, wherein an interior angle between the first and second portions of the cooling unit is equal to 90 degrees.

6. The cooling unit according to claim 1, wherein the orifice is formed on a second external surface of the inlet/outlet portion, said second external surface being opposite said first external surface of the inlet/outlet portion.

7. A cooling module configured to be integrated in an electrical assembly of an electric or hybrid motor vehicle so as to dissipate the heat generated by electronic components of the electrical assembly, the cooling module comprising cooling units respectively according to claim 1.

8. The cooling module according to claim 7, wherein the cooling units are assembled so as to form a fluid cooling circuit configured to convey a cooling fluid.

9. The cooling module according to claim 7, wherein:
a number of cooling units is equal to two,
for each of the cooling units, the first portion comprises a first connection opening, and the second portion comprises a second connection opening;
the first and second connection openings of one of the cooling units are respectively connected, in a sealed manner, to the second connection opening and to the first connection opening of the other of the cooling units.

10. The cooling module according to claim 7, wherein the orifice of one of the cooling units, and that of the other of the cooling units, are respectively used as a fluid inlet and as a fluid outlet of the cooling module.

11. The cooling module according to claim 7, comprising the cooling fluid used to dissipate the heat generated by the electronic components.

12. An electrical assembly for an electric or hybrid motor vehicle, comprising: electronic components; and a cooling module according to claim 7.

13. The electrical assembly according to claim 12, wherein the electronic components comprise one or more power electronic components, and/or one or more capacitive components.

14. The electrical assembly according to claim 12, forming an inverter or a DC-to-DC voltage converter.
